(19) United States
(12) Patent Application Publication
(10) Pub. No.: US 2008/0182380 A1
(43) Pub. Date: Jul. 31, 2008

(54) METHOD FOR MANUFACTURING SEMICONDUCTOR DEVICE

(75) Inventor: Hideaki OKA, Minowa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/970,583

(22) Filed: Jan. 8, 2008

(30) Foreign Application Priority Data
Jan. 26, 2007 (JP) 2007-016424

(51) Int. Cl. H01L 21/782

(52) U.S. Cl. 438/425; 257/E21.7

(57) ABSTRACT

A method for manufacturing a semiconductor device, comprises: (a) forming a first semiconductor layer on a semiconductor substrate in a first region and forming a second semiconductor layer on the semiconductor substrate in a second region, a thickness of the first semiconductor layer being larger than a thickness of the second semiconductor layer; (b) forming a third semiconductor layer on the first semiconductor layer and the second semiconductor layer; (c) forming a first cavity between the third semiconductor layer and the semiconductor substrate in the first region, and a second cavity between the third semiconductor layer and the semiconductor substrate in the second region by removing the first semiconductor layer and the second semiconductor layer, the first cavity and the second cavity having an internal height different each other; (d) forming an insulation layer inside the first cavity and the second cavity so that the first cavity remains a third cavity defined by the insulation layer formed both sides thereof, and the second cavity is filled with the insulation layer; and (e) filling the third cavity with an electrode material.

The entire disclosure of Japanese Patent Application No. 2007-016424, filed Jan. 26, 2007 is expressly incorporated by reference herein.

### BACKGROUND

1. Technical Field

One aspects of the present invention relates to a method for manufacturing a semiconductor device and, in particular, to a technique capable of forming an SOI structure with a back gate electrode and a typical SOI structure in the same substrate.

2. Related Art

A related art is, for example, disclosed in “Separation by Bonding Si Islands (SBSI) for LSI Application,” Second International SiGe technology and Device Meeting, Meeting Abstract, pp. 230-231, May 2004, T. Sakai et al. A method disclosed in the document is called an SBSI method in which an SOI structure is partially formed on a bulk substrate. In the SBSI method, Si/SiGe layer is formed on a Si substrate, and only the SiGe layer is selectively removed by using difference of etching rate between Si and SiGe so as to form a cavity between the Si substrate and the Si layer. Then, each surface of the Si layer exposed at the upper part of the cavity and the Si substrate exposed at the lower part of the cavity is thermally oxidized to form a SiO₂ film (i.e., a BOX layer) between the Si substrate and the Si layer.

In addition, a technique has been examined that forms a back gate structure by applying the SBSI method. In the technique, a first SiGe layer, a first Si layer, a second SiGe layer and a second Si layer are layered on a Si substrate in order, and then only the SiGe layer is selectively etched and removed from the layers. Here, each of the SiGe layer and the Si layer is a single-crystal layer. Then, each surface of the Si layer and the Si substrate exposed inside a cavity is thermally oxidized to form a SiO₂ film. The resulting SiO₂ film insulates the Si substrate and the first Si layer, and the first Si layer and the second Si layer. As a result, the second Si layer can be used as an SOI layer while the first Si layer can be used as a back gate electrode.

An SOI element with the back gate structure (i.e., a transistor formed in the SOI layer) can reduce standby power consumption while keeping an operation speed by controlling threshold voltage with back gate bias. The element is effectively used, in particular, for a circuit requiring lower standby power consumption. On the other hand, a typical SOI element is suitable for high-speed operation since it has no stray capacitance caused by the back gate structure, effectively used for a circuit requiring high-speed operation rather than standby power consumption. It is preferable for a system that these elements having a function different each other are formed on the same substrate.

It is possible in principle that an SOI structure with a back gate electrode and a typical SOI structure without the back gate electrode are formed in the same substrate by the following exemplified manner: a back gate electrode formed on a Si substrate with an oxide film interposed therebetween, a base that is formed on the back gate electrode and has an oxide film, and a Si substrate in which hydrogen ions are implanted are bonded together by a bonding method, and a smart cutting method or the like is applied to form the structures on the same substrate. However, transistors formed in the back gate electrode and the SOI layer are not well aligned. Further, in-house manufacturing lines for SOI substrates are required.

### SUMMARY

An advantage of the invention is to provide a method for manufacturing a semiconductor device that can form an SOI structure with a back gate electrode and a typical SOI structure on the same semiconductor substrate by self-alignment and using typical semiconductor processes.

According to an aspect of the invention, a method for manufacturing a semiconductor device includes: (a) forming a first semiconductor layer on a semiconductor substrate in a first region and forming a second semiconductor layer on the semiconductor substrate in a second region, a thickness of the first semiconductor layer being larger than a thickness of the second semiconductor layer; (b) forming a third semiconductor layer on the first semiconductor layer and the second semiconductor layer; (c) forming a first cavity between the third semiconductor layer and the semiconductor substrate in the first region, and a second cavity between the third semiconductor layer and the semiconductor substrate in the second region by removing the first semiconductor layer and the second semiconductor layer, the first cavity and the second cavity having an internal height different each other; (d) forming an insulation layer inside the first cavity and the second cavity so that the first cavity remains a third cavity defined by the insulation layer formed both sides thereof, and the second cavity is filled with the insulation layer; and (e) filling the third cavity with an electrode material.

In the method, step (c) further may include: (f) forming a first groove penetrating the first semiconductor layer, the second semiconductor layer, and the third semiconductor layer by partially etching the first semiconductor layer, the second semiconductor layer, and the third semiconductor layer; (g) forming a support body supporting the third semiconductor layer at least in the first groove; (h) forming a second groove exposing a side surface of the first semiconductor layer and the second semiconductor layer by partially etching the first semiconductor layer, the second semiconductor layer, and the third semiconductor layer; and (i) etching the first semiconductor layer and the second semiconductor layer through the second groove with an etching condition to form the first cavity and the second cavity. The first semiconductor layer and the second semiconductor layer may be more easily etched than the third semiconductor layer by the etching condition.

According to the method, a structure in which the insulation layer, the electrode material, the insulation layer, and the third semiconductor layer are layered, and a structure in which the insulation layer and the third semiconductor layer are layered can be formed on the same semiconductor substrate. For example, an SOI structure with a back gate electrode and a typical SOI structure without the back gate electrode can be formed on the same substrate by self-alignment, though it is difficult to form them on the same substrate by related arts when the electrode material is used as the back gate electrode.

In the method, step (a) further may include: Q) etching the semiconductor substrate in the first region to form a depressed portion; (k) forming a fourth semiconductor layer only in the first region to fill the depressed portion with the fourth semiconductor layer; and (l) forming a fifth semiconductor layer on the semiconductor substrate in the first region and the second region. The first semiconductor layer may include the fourth semiconductor layer and the fifth semiconductor layer, and the second semiconductor layer may include the fifth semiconductor layer.

According to the method, the surface of the fourth semiconductor layer formed in the first region and the surface of the semiconductor substrate in the second region are on the same line from a sectional view, when the depth value of the depressed portion is set equal to the thickness value of the fourth semiconductor layer. This setting allows the first semiconductor layer and the second semiconductor layer to be formed with a little step, contributing to improve flatness of the semiconductor device.

In the method, step (d) further may include thermally oxidizing an upper surface of the semiconductor substrate and an under surface of the third semiconductor layer inside each of the first cavity and the second cavity to form the insulation layer. According to the method, the insulation layer is easily formed inside the cavity.

In the method, the first semiconductor layer and the second semiconductor layer may be silicon germanium, and the third semiconductor layer may be silicon. The electrode material may be polysilicon including an impurity.

In the method, the electrode material may be one of a metal, a metal silicide, and a metallic nitride. The electrode material may be formed by a chemical vapor deposition method.

### BRIEF DESCRIPTION OF THE DRAWINGS

The invention will be described with reference to the accompanying drawings, wherein like numbers reference like elements.

FIGS. 1A, 1B, 1C and 1D illustrate a method for manufacturing a semiconductor device according to an embodiment of the invention.

FIGS. 2A, 2B, 2C and 2D illustrate the method for manufacturing a semiconductor device according to the embodiment of the invention.

FIGS. 3A, 3B, 3C and 3D illustrate the method for manufacturing a semiconductor device according to the embodiment of the invention.

FIGS. 4A, 4B, 4C and 4D illustrate the method for manufacturing a semiconductor device according to the embodiment of the invention.

FIGS. 5A, 5B, 5C and 5D illustrate the method for manufacturing a semiconductor device according to the embodiment of the invention.

FIGS. 6A, 6B, 6C and 6D illustrate the method for manufacturing a semiconductor device according to the embodiment of the invention.

FIGS. 7A, 7B, 7C and 7D illustrate the method for manufacturing a semiconductor device according to the embodiment of the invention.

FIGS. 8A, 8B, 8C and 8D illustrate the method for manufacturing a semiconductor device according to the embodiment of the invention.

FIGS. 9A, 9B, 9C and 9D illustrate the method for manufacturing a semiconductor device according to the embodiment of the invention.

FIGS. 10A, 10B, 10C and 10D illustrate a method for manufacturing a semiconductor device according to an embodiment of the invention.

FIGS. 11A, 11B, 11C and 11D illustrate a method for manufacturing a semiconductor device according to an embodiment of the invention.

FIGS. 12A, 12B, 12C and 12D illustrate a method for manufacturing a semiconductor device according to an embodiment of the invention.

FIGS. 13A, 13B, 13C and 13D illustrate a method for manufacturing a semiconductor device according to an embodiment of the invention.

FIGS. 14A, 14B, 14C and 14D illustrate a method for manufacturing a semiconductor device according to an embodiment of the invention.

FIGS. 15A, 15B, 15C and 15D illustrate a method for manufacturing a semiconductor device according to an embodiment of the invention.

FIGS. 16A, 16B, 16C and 16D illustrate a method for manufacturing a semiconductor device according to an embodiment of the invention.

FIGS. 17A, 17B, 17C and 17D illustrate a method for manufacturing a semiconductor device according to an embodiment of the invention.

FIGS. 18A, 18B, 18C and 18D illustrate a method for manufacturing a semiconductor device according to an embodiment of the invention.

### DESCRIPTION OF EXEMPLARY EMBODIMENTS

A semiconductor device and a method for manufacturing the device according to an embodiment of the invention will now be described with reference to the accompanying drawings.

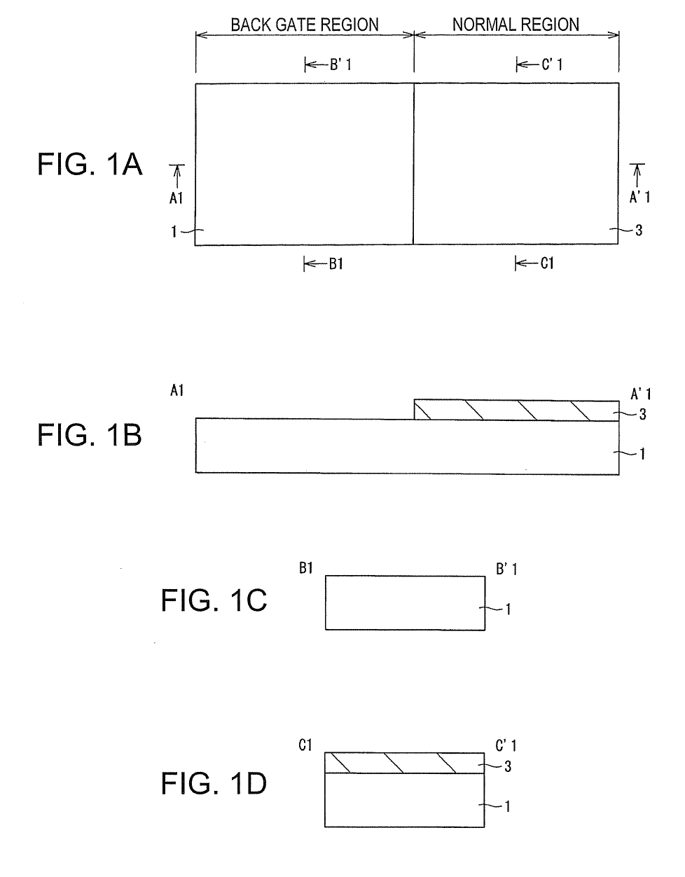

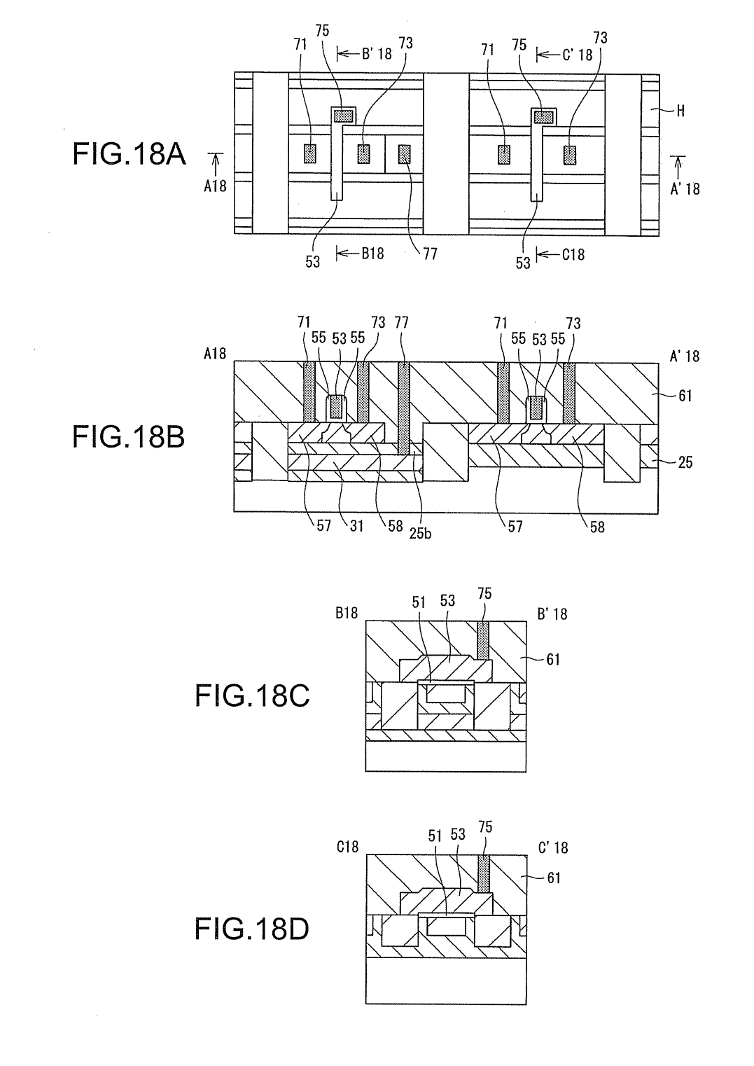

FIGS. 1A to 18A are plane views illustrating a method for manufacturing a semiconductor device according to the embodiment of the invention. FIGS. 1B to 18B are sectional views taken along lines A1-A′1 to A18-A′18 of FIGS. 1B to 18B, respectively. FIGS. 1C to 18C are sectional views taken along lines B1-B′1 to B18-B′18 of FIGS. 1A to 18A, respectively. FIGS. 1D to 18D are sectional views taken along lines C1-C′1 to C18-C′18 of FIGS. 1A to 18A, respectively. In FIG. 18A, an interlayer insulation film is omitted in order to avoid unnecessary complicated drawing.

As shown in FIGS. 1A and 1B, a silicon (Si) substrate 1 has a region in which an SOI structure with a back gate electrode is formed (hereinafter, referred to a back gate region) and a region in which a typical SOI structure without the back gate electrode is formed (hereinafter, referred to a normal region). First, a silicon nitride (SiN) film 3 is formed on the entire upper surface of the Si substrate 1. Then, as shown in FIGS. 1A to 1D, the SiN film 3 is partially etched so as to be removed from the Si substrate 1 in the back gate region while the SiN film 3 remains on the Si substrate 1 in the normal region. The SiN film 3 is formed by a CVD method, for example. The partial etching is performed by photolithography and a dry etching technique, for example.

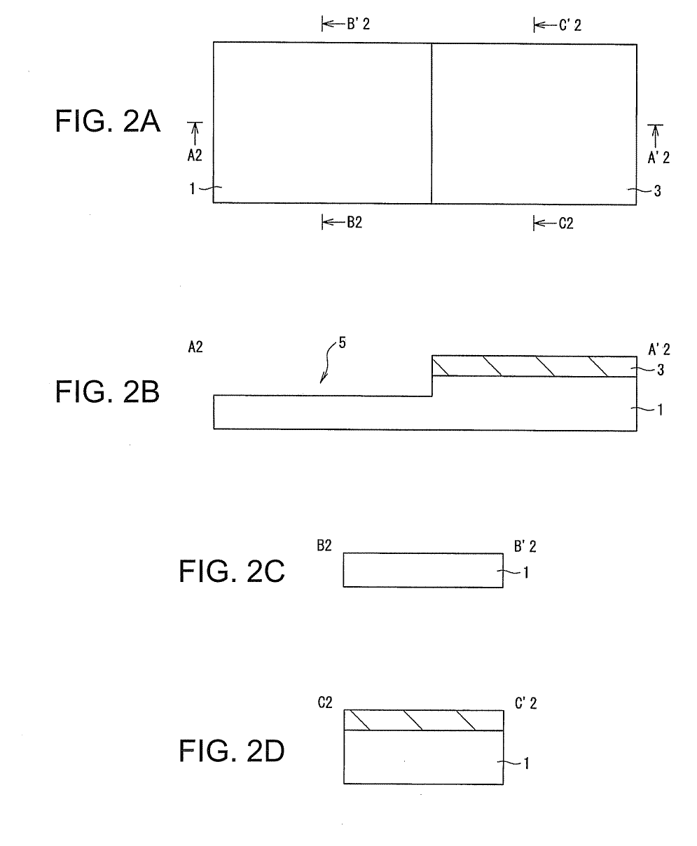

Next, as shown in FIGS. 2A to 2D, the Si substrate 1 in the back gate region is etched with the SiN film 3 as a mask to form a depressed portion 5. The Si substrate 1 is etched by dry etching, for example. The etching amount (i.e., the depth of the depressed portion) is 50 nm to 70 nm, for example. After forming the depressed portion 5 in the back gate region, the SiN film 3 is removed by etching with a heated phosphoric acid solution, for example.

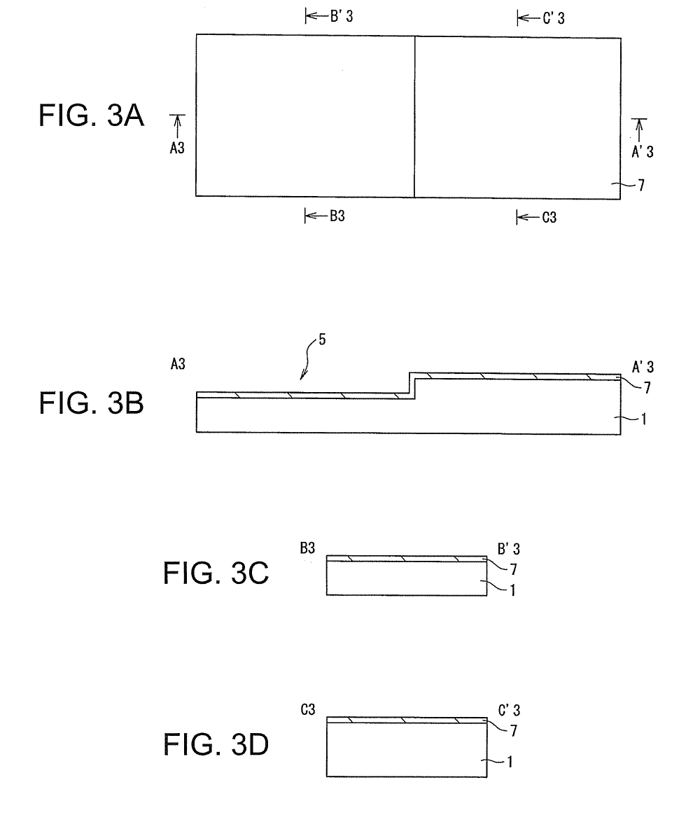

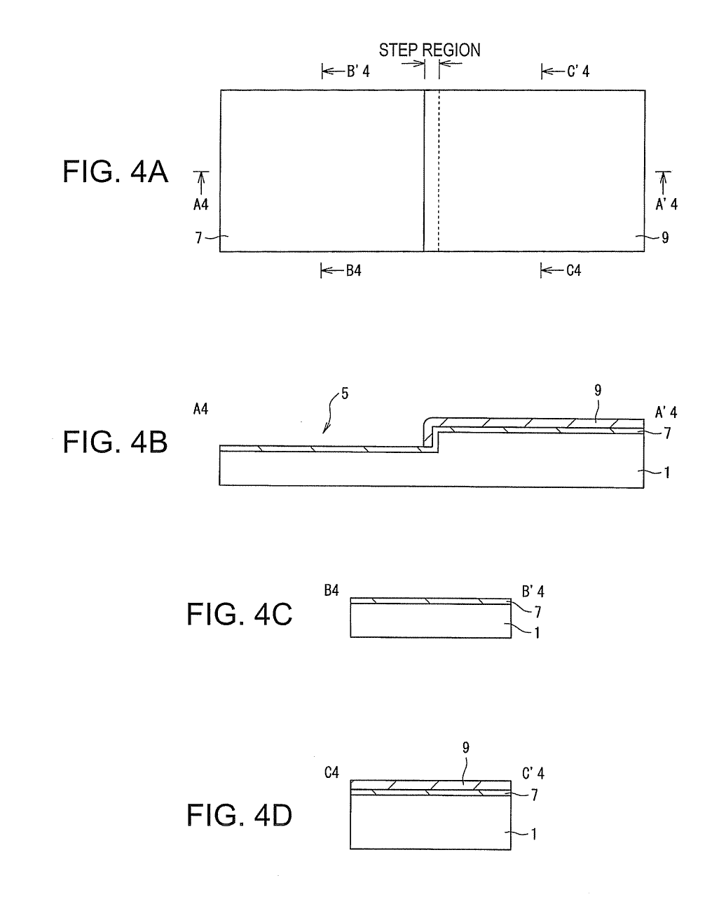

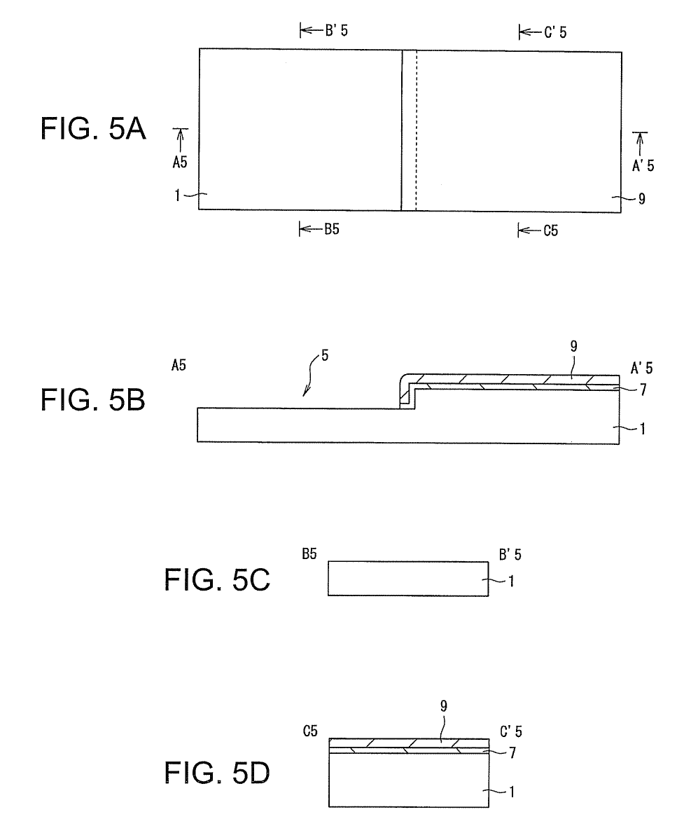

Next, as shown in FIGS. 3A to 3D, a silicon oxide (SiO₂) film 7 is formed on the entire upper surface of the Si substrate 1, followed by a SiN film (not shown) formed on the SiO₂ film 7. The SiO₂ film 7 is formed by thermal oxidization or a CVD method, for example. The SiN film (not shown) is formed by a CVD method, for example. Then, a resist pattern is formed on the SiN film so as to cover the normal region and a step region located between the normal region and the back gate region. The SiN film is removed by etching with the resist pattern as a mask. The SiN film is etched by anisotropic dry etching with the SiO₂ film 7 as an etching stopper. Then, the resist pattern is removed by ashing, for example. As a result, as shown in FIGS. 4A to 4D, the SiN film 9 is removed from the Si substrate 1 in the back gate region while SiN film 9 remains on the Si substrate 1 in the normal region and the step region. Then, the SiO₂ film 7 exposed in the back gate region is removed by wet etching with a HF solution, for example, so as to expose the surface of the Si substrate 1 in the back gate region as shown in FIGS. 5A to 5D.

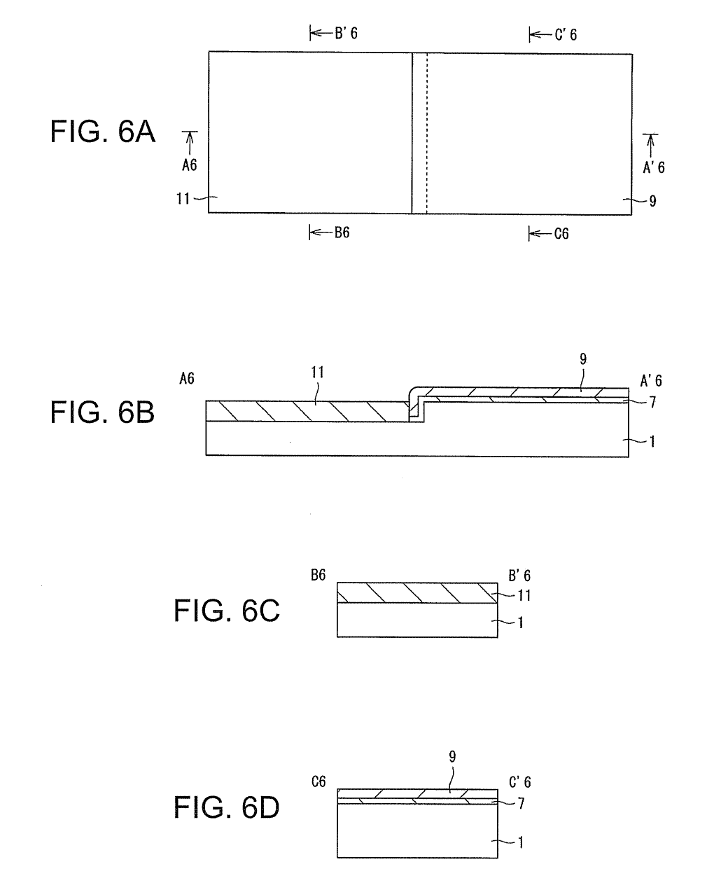

Next, as shown in FIGS. 6A to 6D, a silicon germanium (SiGe) layer 11 of single-crystal is formed only on the Si substrate 1 in the back gate region. The SiGe layer 11 is formed by a selective epitaxial growth method so as to have a thickness of 50 nm to 70 nm, for example. After forming the SiGe layer 11 as shown in FIGS. 6A to 6D, the SiN film 9 and the SiO₂ film 7 under the film 9 are removed by etching. The SiN film 9 is wet etched with a heated phosphoric acid solution, for example. The SiO₂ film 7 is wet etched with a HF solution, for example. As a result, the surface of the Si substrate 1 in the normal region is exposed.

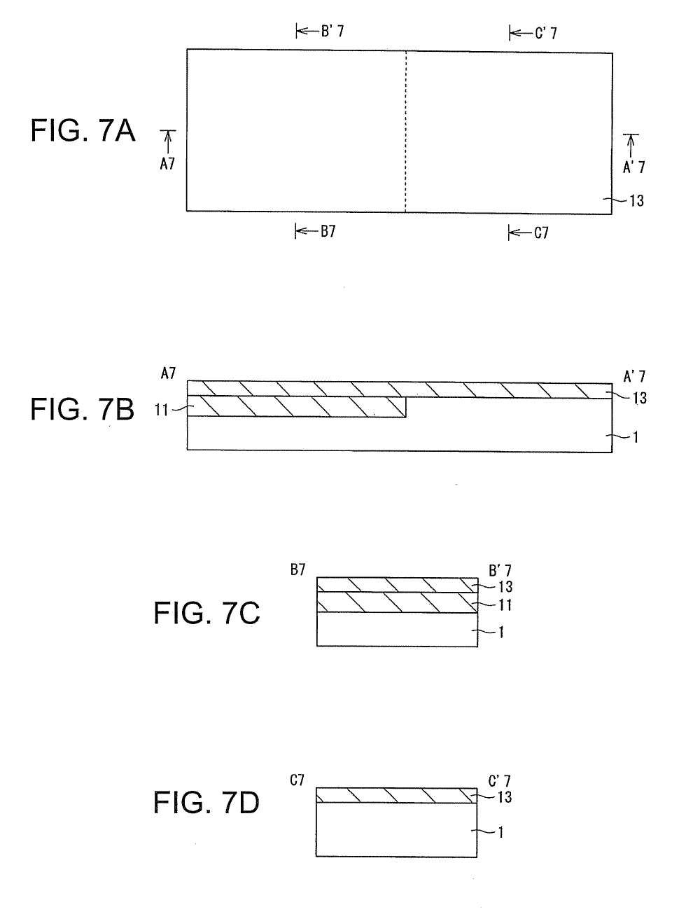

Next, as shown in FIGS. 7A to 7D, a SiGe layer 13 of single-crystal is entirely formed on the Si substrate 1 in the normal region and above the Si substrate 1 in the back gate region. As a result, the SiGe layer 13 is layered on the SiGe layer 11 in the back gate region while the SiGe layer 13 is directly formed on the Si substrate 1 in the normal region. The SiGe layer 13 is entirely formed by an epitaxial growth method so as to have a thickness of 20 nm to 30 nm, for example. In this embodiment, the depth value of the depressed portion 5 is equal to the thickness value of the SiGe layer 11. The surface of the SiGe layer 11 in the back gate region and the surface of the Si substrate 1 in the normal region are on the same line in a sectional view. Thus, the SiGe layer 13 is formed with a little step between the back gate region and the normal region, contributing to improve the flatness of the semiconductor device.

In the step region located between the normal and back gate regions, the SiGe layer 13 growths on the side surface of the SiGe layer 11 formed in the back gate region, and the SiGe layer 13 growths upwardly from the surface of the Si substrate 1. In FIGS. 7A to 7D, however, the growing portion is omitted in order to avoid unnecessary complicated drawings.

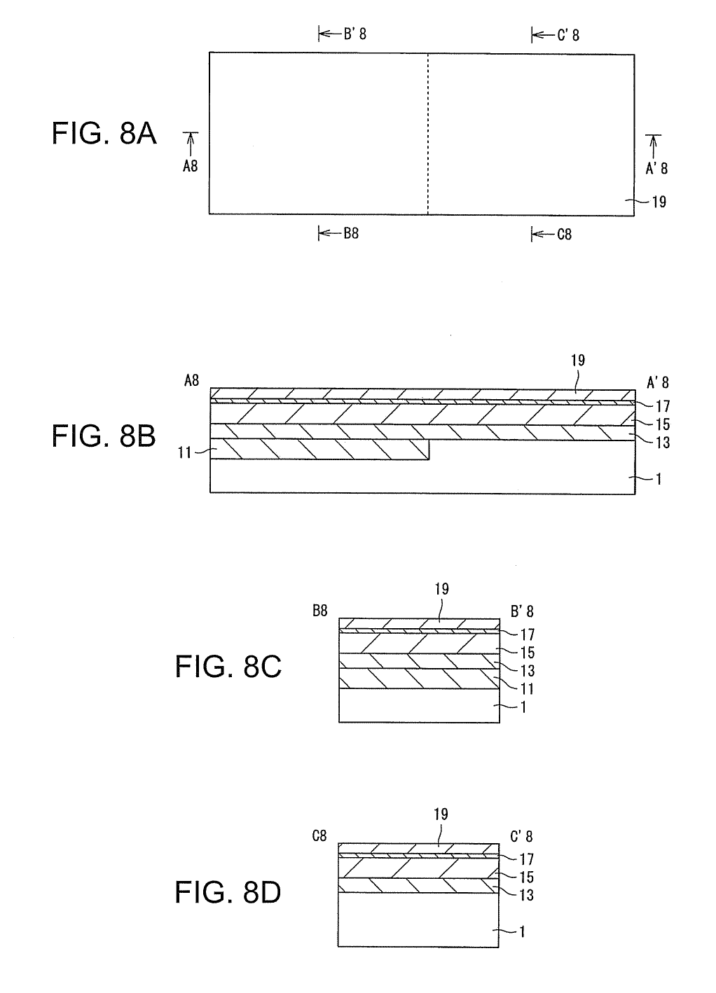

Next, as shown in FIGS. 8A to 8D, a Si layer 15 of single-crystal is layered on the SiGe layer 13. The Si layer 15 is entirely formed by an epitaxial growth method, for example. Then, the Si layer 15 is thermally oxidized to form a SiO₂ film 17 on the surface. Next, a SiN film 19 is formed on the entire surface of the SiO₂ film 17 by a CVD method. The SiN film 19 functions as an oxidation prevention film to prevent the Si layer 15 from being oxidized and also as a stopper layer in chemical mechanical polishing (CMP) in a later process. The method for forming the SiO₂ film 17 is not limited to thermal oxidization. For example, a CVD method can be applied.

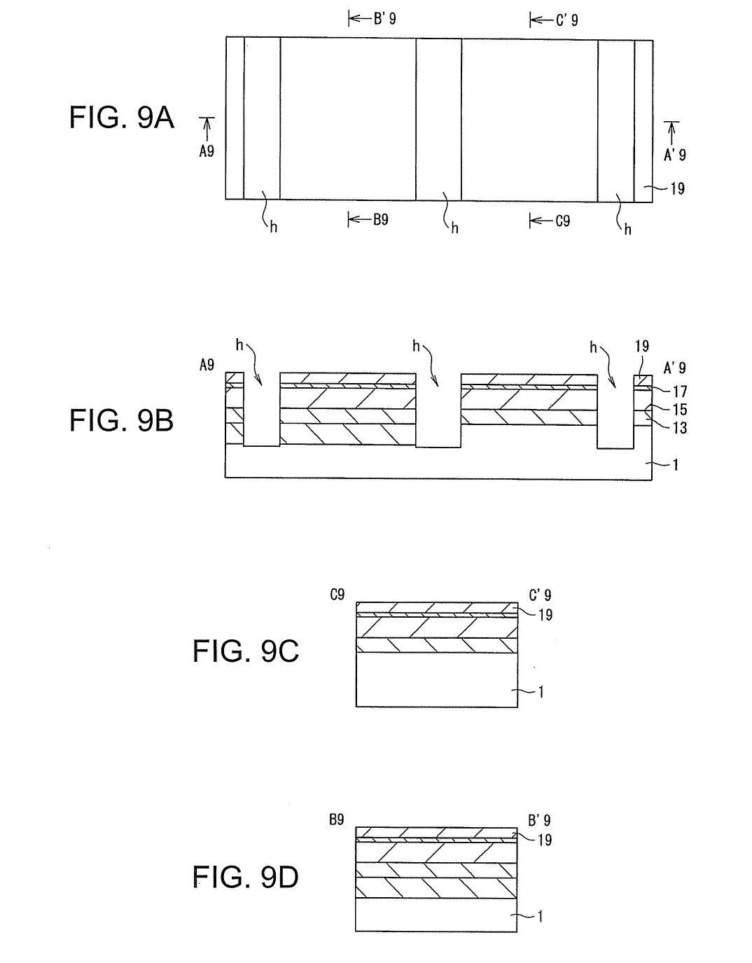

Next, as shown in FIGS. 9A to 9D, the SiN film 19, the SiO₂ film 17, the Si layer 15 and the SiGe layer are partially etched by photolithography and an etching technique in order in a region overlapped with an element isolation region (i.e., a region in which an SOI structure is not formed) in a plan view. In the back gate region, the SiGe layers 13 and 11 are partially etched in order. In the normal region, the SiGe layer is etched. As a result, a support body hole h is formed that penetrates the Si layer 15, the SiGe layer 13 and the SiGe layer 11, and reaches the Si substrate 1 serving as the bottom. In the etching step forming the support body hole h, the etching may be stopped at the surface of the Si substrate 1, or a recess may be formed by over etching the Si substrate 1 as shown in FIG. 9B.

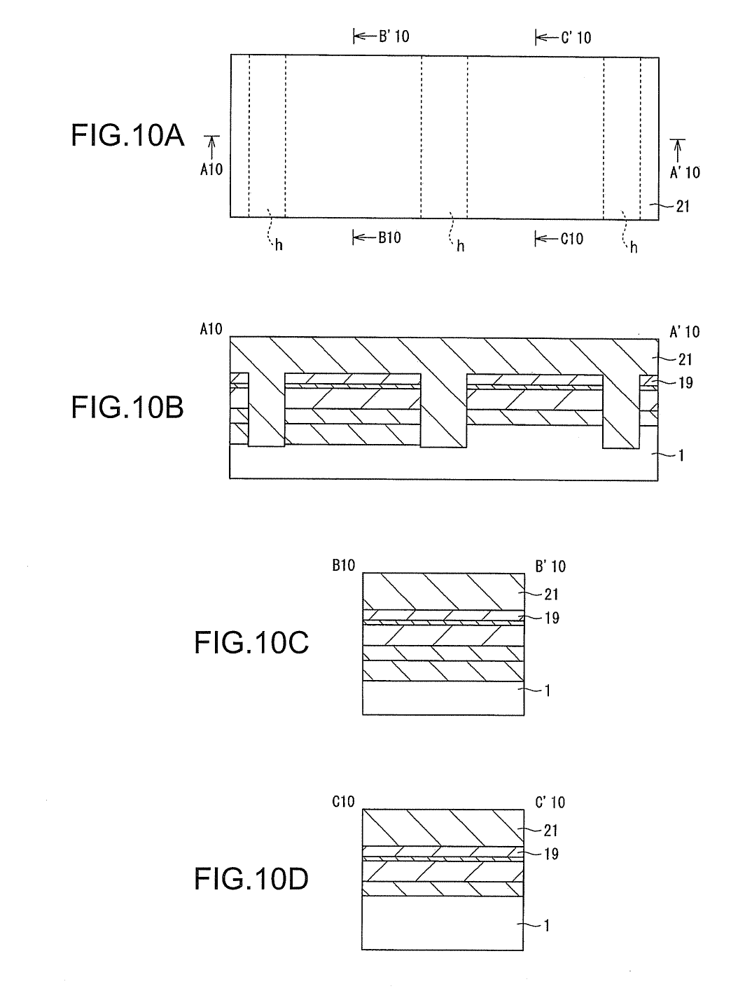

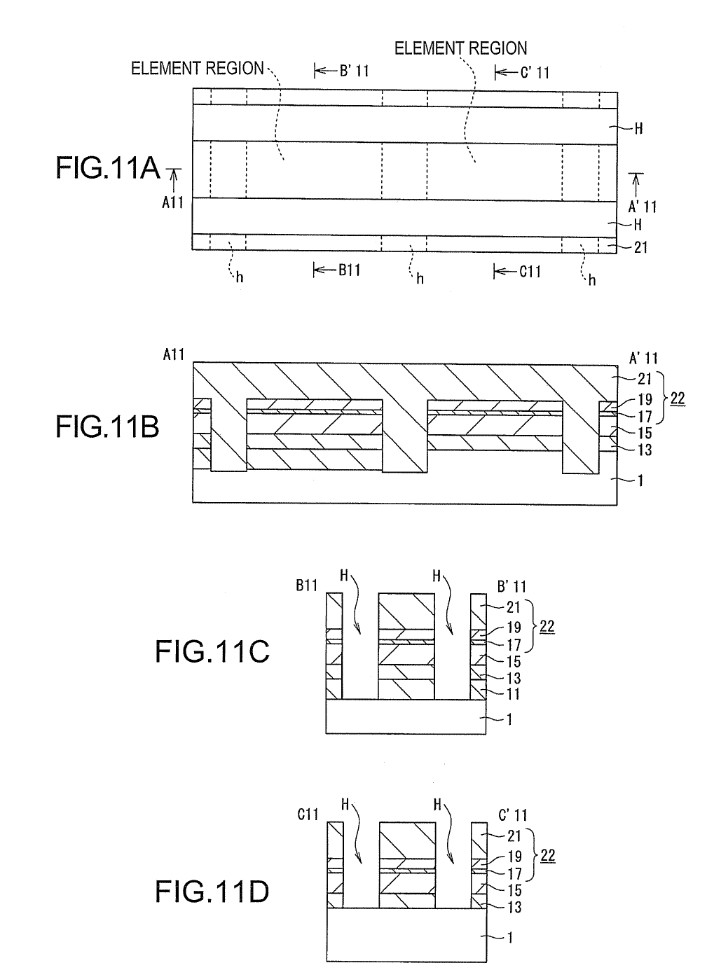

Next, as shown in FIGS. 10A to 10D, a support body film 21 is formed on the entire surface of the Si substrate 1 so as to fill the support body hole h. The support body film 21, for example, is a silicon oxide (SiO₂) film, and it is formed by a CVD method, for example. Next, as shown in FIGS. 11A to 11D, the support body film 21, the SiN film 19, the SiO₂ film 17, the Si layer 15 and the SiGe layer are partially etched in order by photolithography and an etching technique in a region overlapped with the element isolation region in a plan view. In the back gate region, the SiGe layers 13 and 11 are partially etched in order. In the normal region, the SiGe is etched. As a result, a support body 22 and a groove H are formed. The support body 22 is composed of the support body film 21, the SiN film 19, and the SiO₂ film 17. The groove H exposes the side surfaces of the Si layer 15 and the SiGe layers 13 and 11, and reaches the Si substrate 1 serving as the bottom. Here, the groove H serves as an inlet of an etchant when the SiGe layers 13 and 11 are etched in a later step.

In the etching step forming the groove H, the etching may be stopped at the surface of the Si substrate 1, or a recess may be formed by over etching the Si substrate 1 as shown in FIGS. 11C and 11D. In FIG. 11A, an element region (i.e., a region in which an SOI structure is formed) is defined as a region surrounded by the support body hole h and the groove H in a plan view.

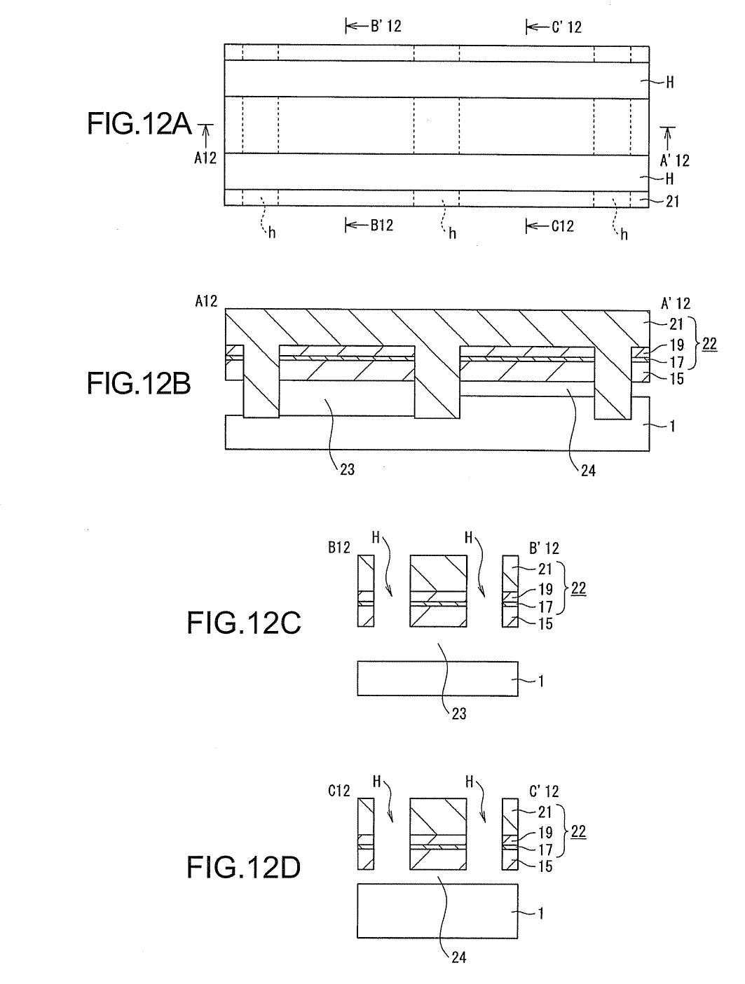

Then, the Si layer 15, the SiGe layer 13, and the SiGe layer 11 are etched by contacting an etchant, such as a hydrofluoric-nitric acid solution, with respective sides thereof through the groove H to selectively remove the SiGe layers 13 and 11. As a result, as shown in FIGS. 12A to 12D, a cavity 23 is formed between the Si substrate 1 and the Si layer 15 in the back gate region while a cavity 24 is formed between the Si substrate 1 and the Si layer 15 in the normal region. In wet etching using a hydrofluoric-nitric acid solution, since an etching rate of SiGe is higher than that of Si, (that is, the etching selectivity with respect to Si is high), only the SiGe layer is removed by etching, while the Si layer 15 remains. In the middle of forming the cavities 23 and 24, the top surface and the side surface of the Si layer 15 are supported by the support body 22.

In this embodiment, the SiGe layers 13 and 11 are formed in the back gate region while the SiGe layer 13 is formed in the normal region. The wet etching through the groove H entirely removes these SiGe layers. As a result, the internal height of the cavity 23 formed in the back gate region is different from that of the cavity 24 formed in the normal region. As shown in FIGS. 12B to 12D, the cavity 23 has the higher internal height (clearance) than that of the cavity 24.

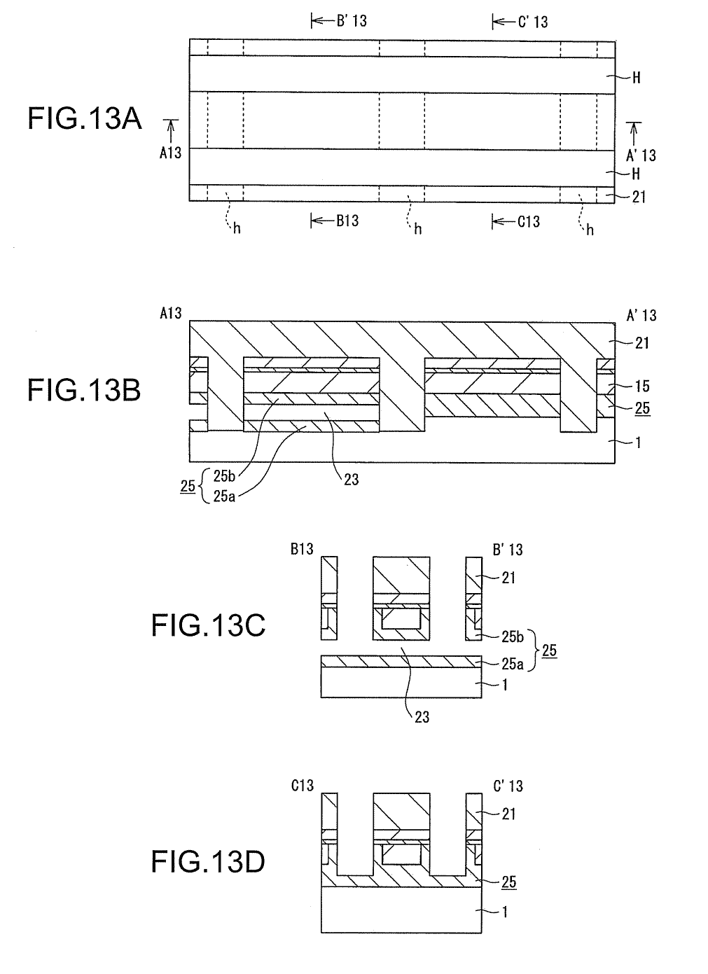

Next, the Si substrate 1 is cleaned with a dilute hydrofluoric acid (HF) solution. Then, the Si substrate 1 is subjected to a heat treatment in an oxidation atmosphere, such as oxygen (O₂). The heat treatment oxidizes Si on the surfaces of the Si layer 15 and the Si substrate 1 to form a SiO₂ film 25 on each surface as shown in FIGS. 13A to 13D.

In the embodiment, the heat treatment is carried out so that the cavity in the normal region is fully filled with the film 25 while the cavity 23 in the back gate region is not fully filled with the film 25. That is, in the back gate region, the SiO₂ film 25a is formed on the upper surface of the Si substrate 1 while a SiO₂ film 25b is formed on the lower surface of the Si layer 15 simultaneously. The cavity 23 remains between the SiO₂ films 25a and 25b. In the normal region, the SiO₂ film 25 is formed so that the cavity is fully filled with the film 25. The thermal treatment conditions vary depending on each internal height of the cavities 23 and 24 (i.e., the thickness of SiGe layer) before the heat treatment. It is preferable that the optimum heat treatment temperature and time, gas, gas flow rate and the like be obtained by experiments or simulations prior to start the manufacturing of a semiconductor device.

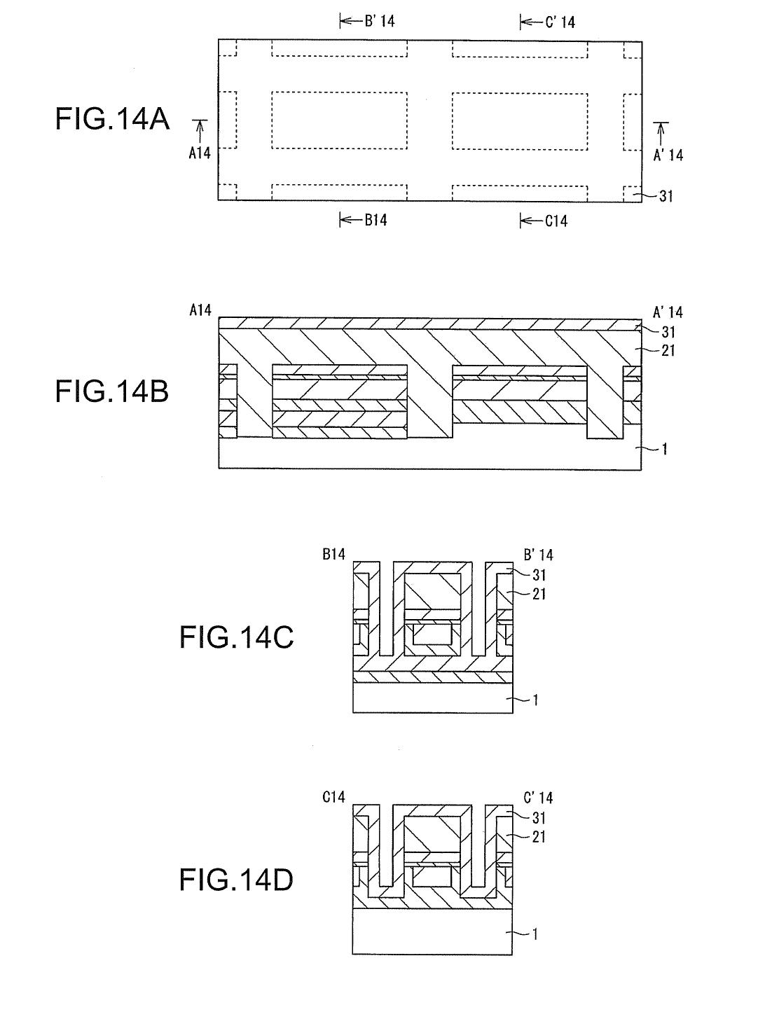

Next, as shown in FIGS. 14A to 14D, a polysilicon (poly-Si) layer 31 containing a conductive impurity, such as phosphorus or boron, is entirely formed above the Si substrate 1 so that the cavity in the back gate region is fully filled with the polysilicon layer 31. The poly-Si layer 31 is formed so as to be sandwiched with the SiO₂ films 25a and 25b from up-and-down sides since the SiO₂ films 25a and 25b have been formed inside the cavity in the back gate region as described above. The poly-Si layer 31 is formed by a CVD method, for example. In the invention, first, an amorphous silicon (a-Si) layer containing a conductive impurity may be entirely formed above the Si substrate 1 so that the cavity is filled with the layer, and then the a-Si layer may be turned into polysilicon by heat treatment. Alternatively, poly-silicon containing no impurity may be formed, and then an impurity may be implanted by an ion implantation method prior to a step forming a transistor. Instead of the poly-Si layer 31, metals, metal silicides, metallic nitrides, or the like may be used to fill the cavity. Any film made of a-Si, metals, metal silicides, or metal nitrides can be formed by a CVD method.

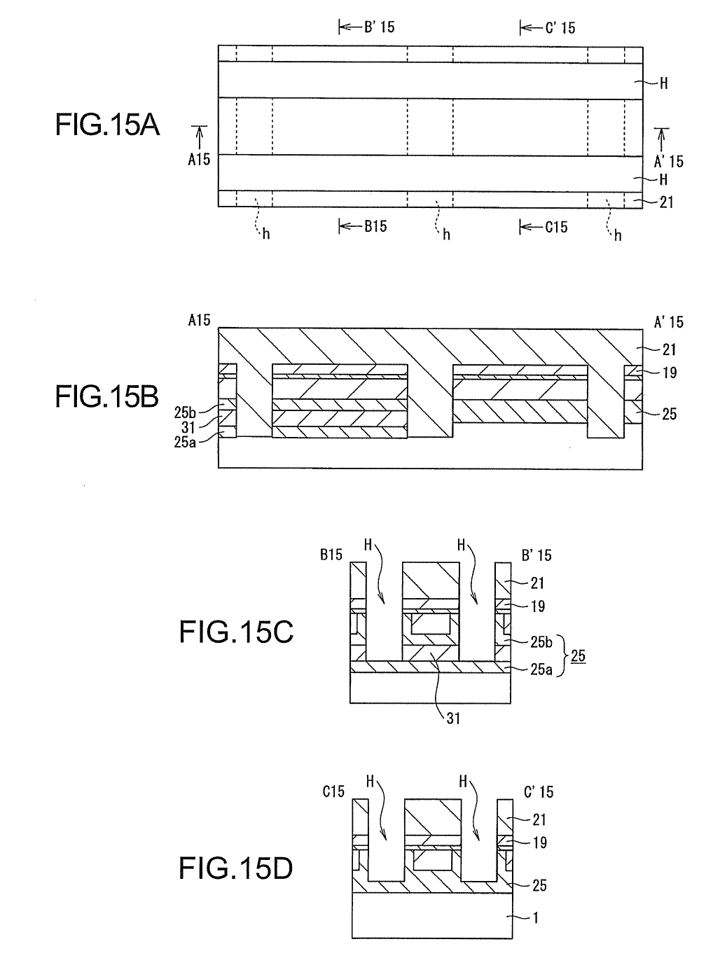

Next, the poly-Si layer 31, shown in FIGS. 14A to 14D, is etched back to be partially removed. In the etching-back step, an anisotropic dry etching is performed, followed by an isotropic etching, or an isotropic etching is performed from beginning to end. As a result, the poly-Si layer 31 is removed from the surface of the support body film 21 and the inside the groove H while it remains inside the cavity in the back gate region as shown in FIGS. 15A to 15D.

In the step removing the poly-Si layer 31, a SiO₂ film may be formed by thermally oxidizing the poly-Si layer 31 instead of performing the etching back, and then the poly-Si layer 31 may be removed by etching the SiO₂ film with a HF solution. As shown in FIGS. 15B to 15D, the SiN film 19 is formed above the poly-Si layer 31 formed in the cavity, and the SiN film 19 has a function of antioxidation as used in a LOCOS method. Thus, even when the thermal oxidation is carried out as described above, only the poly-Si layer 31 formed inside the groove H and on the SiN film can be oxidized while the poly-Si layer 31 formed inside the cavity is prevented from being oxidized.

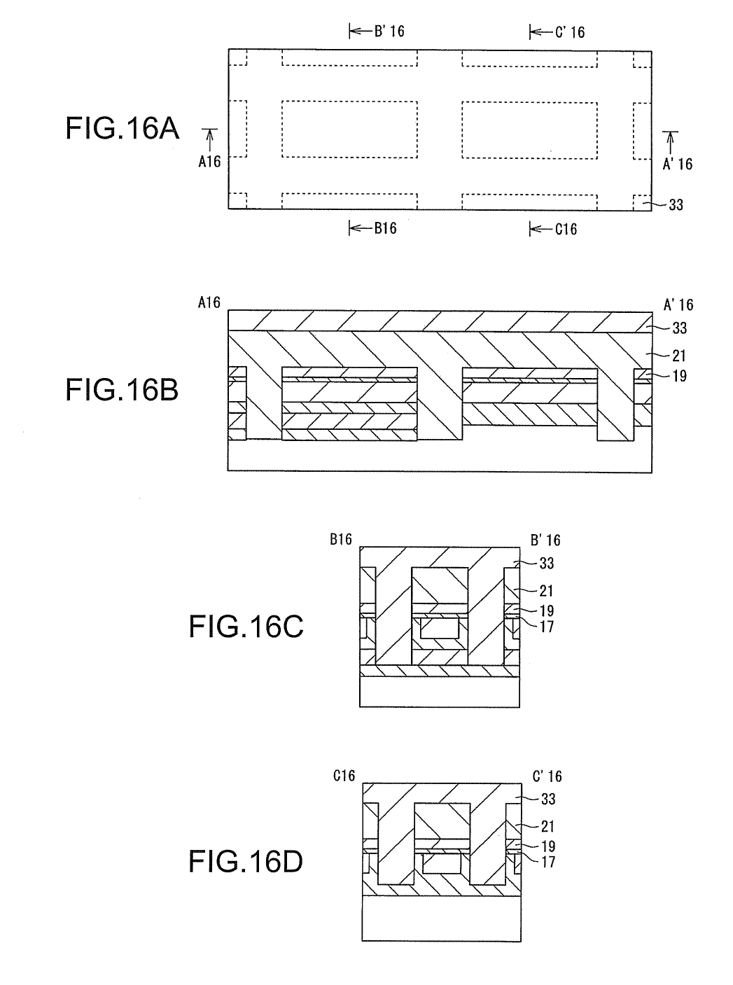

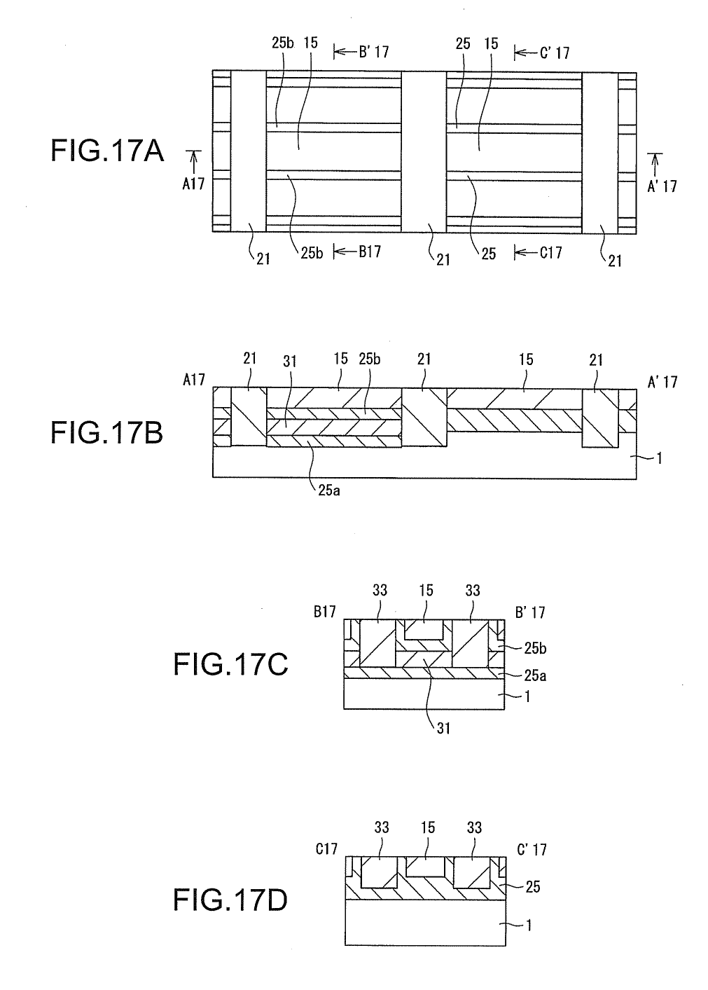

Next, as shown in FIGS. 16A to 16D, an insulation film 33 is entirely formed, for example, by a CVD method, above the Si substrate 1 so as to fill the groove H. The insulation film 33 is a SiO₂ film, for example. Then, the insulation film 33 entirely covering above the Si substrate 1 and the support body film 21 under the film 33 are removed and planarized by CMP, for example. As described above, the SiN film 19 functions as a stopper layer in the planarization process by CMP. After the planarization process, the SiN film 19 and the SiO₂ film 17 are removed by wet etching. The SiN film is etched by using a heated phosphoric acid solution, for example, while the SiO₂ film is etched by using a dilute hydrofluoric acid solution, for example. As a result, the surface of the Si layer 15 is exposed in the back gate region and the normal region, as shown in FIGS. 17A to 17D.

Next, in FIGS. 17A to 17D, the surface of the Si layer 15 in the back gate and normal regions is thermally oxidized to form a gate insulation film. Then, a poly-Si layer is formed by a CVD method, for example, on the silicon layer 15 on which the gate insulation film has been formed. Subsequently, the poly-Si layer is patterned by photolithography and an etching technique. As a result, a gate electrode 53 is formed on the insulation film 51 in the back gate and normal regions, as shown in FIGS. 18A to 18D. The gate electrode material is not limited to poly-Si.

Next, an impurity, such as As, P, and B, is ion implanted into the Si layer with the gate electrode 53 as a mask to form a lightly doped drain (LDD). Then, an insulating layer is formed on the silicon layer provided with the LDD, by a CVD method or the like. Next, a sidewall 55 is formed on the sidewalls of the gate electrode 53 by etching back the insulating layer by anisotropic etching, such as RIE. Next, an impurity, such as As, P, and B, is ion implanted into the Si layer with the gate electrode 53 and the sidewall 55 as a mask to form a source 57 and a drain 58 having the lightly doped drain (LDD).

Next, as shown in FIGS. 18A to 18D, an interlayer insulation film 61 is deposited on the gate electrode 53 by a CVD method or the like after the Si layer is partially removed by etching. Then, a contact hole is formed on each of the source 57, the drain 58, the gate electrode 53, and the poly-Si layer 31 by partially etching and removing the interlayer insulation layer 61, the SiO₂ film 25b and the like by photolithography and an etching technique. After subsequent metal forming and patterning, a source contact electrode 71, a drain contact electrode 73, a gate contact electrode 75, and a back gate contact electrode 77 are formed.

As described as above, according to the embodiment, an SOI structure provided with the back gate electrode in which the SiO₂ film 25a, the poly-Si layer 31, the SiO₂ film 25b, and the Si layer 15 are layered, and a typical SOI structure in which the SiO₂ film 25 and the Si layer 15 can be formed on the same Si substrate 1.

That is, an SOI element with a back gate electrode and a typical SOI element without the back gate electrode can be formed on the same substrate by self-alignment and using typical semiconductor processes, though it is difficult to form them in such manner by related arts.

Consequently, standby power consumption can be reduced while keeping an operation speed by controlling threshold voltage with back gate bias, in the back gate structure. The element is effectively used, in particular, for a circuit requiring lower standby power consumption. On the other hand, the typical SOI element is suitable for high-speed operation since it has no stray capacitance caused by the back gate structure, effectively used for a circuit requiring high-speed operation rather than standby power consumption. These elements having a function different each other can be provided on the same substrate.

In the embodiment, the back gate region exemplarily corresponds to “first region” while the normal region exemplarily corresponds to “second region” of the invention. The Si substrate 1, the SiGe layers 11 and 13 layered in the back gate region, and the SiGe layer 13 formed in the normal region exemplarily correspond to “semiconductor substrate,” “first semiconductor layer,” and “second semiconductor layer” of the invention, respectively. Further, the SiGe layer 11, and the SiGe layer 13 exemplarily correspond to “fourth semiconductor layer,” and “fifth semiconductor layer” of the invention, respectively. Further, the Si layer 15, the SiO₂ film 25, and the poly-Si layer 31 exemplarily correspond to “third semiconductor layer,” “insulation layer,” and “electrode material” of the invention, respectively. Further, the support body hole h, and the grove H exemplarily correspond to “first groove” and “second groove” of the invention, respectively.

What is claimed is:

1. A method for manufacturing a semiconductor device, comprising:
(a) forming a first semiconductor layer on a semiconductor substrate in a first region and forming a second semiconductor layer on the semiconductor substrate in a second region, wherein a thickness of the first semiconductor layer is larger than a thickness of the second semiconductor layer;
(b) forming a third semiconductor layer on the first semiconductor layer and the second semiconductor layer;
(c) forming a first cavity between the third semiconductor layer and the semiconductor substrate in the first region, and a second cavity between the third semiconductor layer and the semiconductor substrate in the second region by removing the first semiconductor layer and the second semiconductor layer, wherein the first cavity and the second cavity have an internal height different each other;
(d) forming an insulation layer inside the first cavity and the second cavity so that the first cavity remains a third cavity defined by the insulation layer formed both sides thereof, and the second cavity is filled with the insulation layer; and
(e) filling the third cavity with an electrode material.

2. The method for manufacturing a semiconductor device according to claim 1, wherein step (c) further includes:
(f) forming a first groove penetrating the first semiconductor layer, the second semiconductor layer, and the third semiconductor layer by partially etching the first semiconductor layer, the second semiconductor layer, and the third semiconductor layer;
(g) forming a support body supporting the third semiconductor layer at least in the first groove;
(h) forming a second groove exposing a side surface of the first semiconductor layer and the second semiconductor layer by partially etching the first semiconductor layer, the second semiconductor layer, and the third semiconductor layer; and
(i) etching the first semiconductor layer and the second semiconductor layer through the second groove with an etching condition to form the first cavity and the second cavity, wherein the first semiconductor layer and the second semiconductor layer are more easily etched than the third semiconductor layer by the etching condition.

3. The method for manufacturing a semiconductor device according to claim 1, wherein step (a) further includes:
(j) etching the semiconductor substrate in the first region to form a depressed portion;
(k) forming a fourth semiconductor layer only in the first region to fill the depressed portion with the fourth semiconductor layer; and
(l) forming a fifth semiconductor layer on the semiconductor substrate in the first region and the second region, wherein the first semiconductor layer includes the fourth semiconductor layer and the fifth semiconductor layer, and the second semiconductor layer includes the fifth semiconductor layer.

4. The method for manufacturing a semiconductor device according to claim 1, wherein step (d) further includes thermally oxidizing an upper surface of the semiconductor substrate and an under surface of the third semiconductor layer inside each of the first cavity and the second cavity to form the insulation layer.

5. The method for manufacturing a semiconductor device according to claim 1, wherein the first semiconductor layer and the second semiconductor layer are silicon germanium, and the third semiconductor layer is silicon.

6. The method for manufacturing a semiconductor device according to claim 1, wherein the electrode material is polysilicon including an impurity.

7. The method for manufacturing a semiconductor device according to claim 1, wherein the electrode material is one of a metal, a metal silicide, and a metallic nitride.

8. The method for manufacturing a semiconductor device according to claim 1, wherein the electrode material is formed by a chemical vapor deposition method.
